(19) United States
(12) Patent Application Publication
(10) Pub. No.: US 2024/0282649 A1
(43) Pub. Date: Aug. 22, 2024

(54) SUBSTRATE SUPPORT

(71) Applicant: Tokyo Ohka Kogyo Co., Ltd., Kawasaki-shi (JP)

(72) Inventors: Yubun Kikuchi, Kawasaki-shi (JP); Yoshihiro Yamada, Kawasaki-shi (JP); Ryuma Mizusawa, Kawasaki-shi (JP)

(21) Appl. No.: 18/431,275

(22) Filed: Feb. 2, 2024

(30) Foreign Application Priority Data
Feb. 21, 2023 (JP) 2023-025033

(51) Int. Cl. H01L 23/13; H01L 23/492

(52) U.S. Cl. CPC H01L 23/13; H01L 23/4926

(57) ABSTRACT

A substrate support that allows for effortless debonding of a circuit pattern, the substrate support including a base material having a bonding surface to which a semiconductor substrate (circuit pattern) is bonded; and an adhesive layer having a pattern of dots formed in at least a portion of the bonding surface.

### CROSS-REFERENCE TO RELATED APPLICATIONS

This application claims priority to Japanese Patent Application No. 2023-025033 filed Feb. 21, 2023, the entire content of which is incorporated herein by reference.

### BACKGROUND OF THE INVENTION

### Technical Field

The present invention relates to a substrate support.

### Related Art

There is a proposal to bond a substrate support to the surface having circuit patterns (semiconductor devices) of a semiconductor substrate (for example, see Patent Literature 1).

Patent Literature 1: Japanese Unexamined Patent Application, First Publication No. 2010-42469

Patent Document 1 discloses a laminate in which an adhesive layer is formed on the entire upper surface of a substrate support, and the substrate support and a semiconductor substrate are bonded together. In this laminate, the adhesive layer is formed on the entire upper surface of the substrate support, expanding the bonding area and thereby increasing the adhesion between the substrate support and the semiconductor substrate. Consequently, picking up individual circuit patterns of the semiconductor substrate in later stages may become difficult, for example. Moreover, applying excessive force to debond the circuit pattern from the substrate support during the pickup process poses a risk of damaging the circuit pattern.

### SUMMARY OF THE INVENTION

The present invention has an object of providing a substrate support that allows for effortless debonding of circuit patterns.

A substrate support according to an aspect of the present invention includes: a base material having a bonding surface to which a semiconductor substrate is bonded; and an adhesive layer having a pattern of dots formed in at least a portion of the bonding surface.

According to such an aspect of the present invention, because the adhesive layer between the base material and the semiconductor substrate is a dot pattern, it is possible to bond the substrate support and the semiconductor substrate with low adhesion, in contrast to the configuration where adhesive is provided over the entire upper surface of the substrate support. As a result, for instance, when picking up a circuit pattern from the substrate support, the circuit pattern need not be debonded forcefully from the substrate support. Therefore, the pickup of circuit patterns can be expedited, enabling the efficient production of the semiconductor devices. Furthermore, because the adhesion between the substrate support and the semiconductor substrate is low, it is possible to suppress damage to the circuit pattern when debonding it from the substrate support.

### BRIEF DESCRIPTION OF THE DRAWINGS

FIG. 1 is a side view and a partially enlarged view showing an example of a substrate support according to First Embodiment.

FIG. 2A and FIG. 2B are examples of partially enlarged plan views of the substrate support.

FIG. 2A is a diagram showing an example of a dot pattern.

FIG. 2B is a diagram showing an example of a dot pattern according to Modified Example 1.

FIG. 3A and FIG. 3B are examples of partially enlarged plan views of the substrate support.

FIG. 3A is a diagram showing an example of a dot pattern according to Modified Example 2.

FIG. 3B is a diagram showing an example of a dot pattern according to Modified Example 3.

FIG. 4 is an exemplified plan view of an enlarged portion of the substrate support, showing a dot pattern according to Modified Example 4.

FIG. 5 is a plan view showing an example of a substrate support according to Second Embodiment.

FIG. 6 is a plan view showing an example of a substrate support according to Third Embodiment.

FIG. 7A is a plan view showing a substrate support according to Modified Example 5.

FIG. 7B is a plan view showing a substrate support according to Modified Example 6.

FIG. 8 is a plan view showing an example of a substrate support according to Fourth Embodiment.

FIG. 9 is a side view showing a dot pattern example.

FIG. 10A is a side view showing a dot pattern according to Modified Example 7.

FIG. 10B is a side view showing a dot pattern according to Modified Example 8.

FIG. 11A, FIG. 11B, and FIG. 11C show an example of a method for producing circuit patterns (semiconductor devices).

FIG. 11A is a diagram showing a state in which a laminate has been produced.

FIG. 11B is a diagram showing a state in which the semiconductor substrate has been subjected to polishing.

FIG. 11C is a diagram showing a state in which the semiconductor substrate has been diced.

FIG. 12A, FIG. 12B, and FIG. 12C show an example of a method for producing circuit patterns (semiconductor devices).

FIG. 12A is a diagram showing a state in which the substrate support is being bonded to the semiconductor substrate.

FIG. 12B is a diagram showing a step of debonding a first support.

FIG. 12C is a diagram showing a state in which the semiconductor substrate is being cleaned.

FIG. 13 is a diagram showing a state in which a circuit pattern has been picked up from the substrate support.

FIG. 14 is a diagram showing test results of the substrate support in Examples and Comparative Examples.

### DETAILED DESCRIPTION OF THE INVENTION

The following describes embodiments with reference to the drawings. However, the present invention is not limited to the embodiments. In the drawings, scale is changed as necessary to illustrate the embodiments, such as by omitting, enlarging or emphasizing some portions, and shapes, dimensions, and other characteristics may differ from the actual product.

### First Embodiment

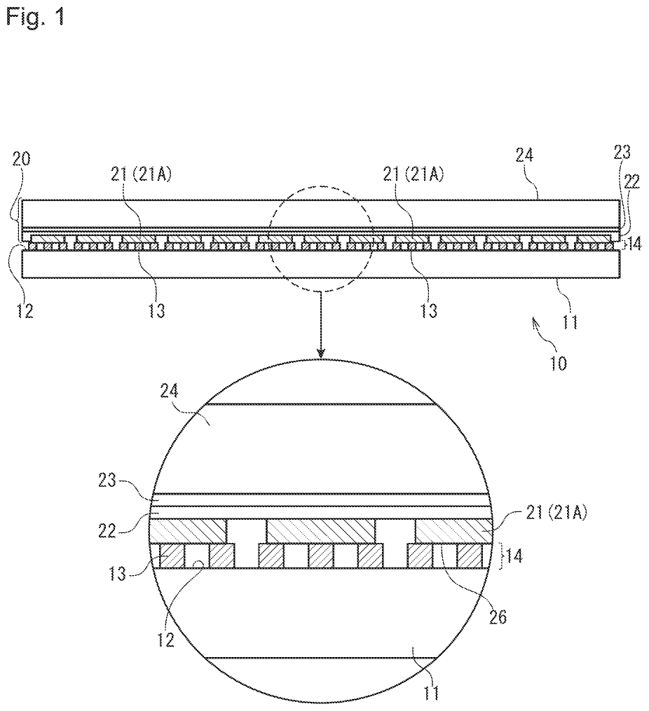

FIG. 1 is a side view and a partially enlarged view showing an example of a substrate support 10 according to First Embodiment. FIG. 1 shows a state in which the substrate support 10 is applied to a laminate 20. As shown in FIG. 1, the substrate support 10 supports the laminate 20 by bonding to a semiconductor substrate 21 (circuit patterns 21A) in the laminate 20. The substrate support 10 includes a base material 11, a bonding surface 12, and dots 13. Examples of the base material 11 include a glass substrate and a silicon wafer, but a silicon wafer is preferred. The shape, in plan view, of the base material 11 is formed in, for example, a circular shape to match the shape of the semiconductor substrate (semiconductor wafer) 21, but is not particularly limited and may be formed in a rectangular shape, a polygonal shape, an elliptical shape, or an elongated elliptical shape.

Dots 13 are formed on the bonding surface 12. The dots 13 serve as the adhesive layer 14 for bonding the laminate 20. The dots 13 are formed in a protruding manner above the bonding surface 12 of the base material 11. For the dots 13 (adhesive layer 14), a composition having adhesion (adhesive properties) that allows for debonding of the circuit patterns 21A, which will be described later, from the base material 11 is used. The adhesion (adhesive properties) of the dots 13 with respect to the semiconductor substrate 21 is lower than that of a first adhesive layer 22 described later.

In the enlarged view of FIG. 1, three dots 13 are in contact with a second surface 26 of the semiconductor substrate 21 (laminate 20), however, the number of dots 13 in contact is arbitrary. As the composition for forming the dots 13, for example, a resist is used. While the resist is not strictly limited to positive or negative types, a negative-type resist (hereinafter, referred to as “negative resist”) is preferred.

Examples of the negative resist include a cationic-polymerization-type negative resist, a radical-polymerization-type negative resist, or a photo-crosslinking-type negative resist. Among these, a cationic-polymerization-type negative resist is preferred. Examples of the cationic-polymerization-type negative resist include a mixture of an epoxy resin, a photoacid generator, and a plasticizer such as acrylic and urethane. Examples of the photoacid generator include compounds such as triarylsulfonium salts. Examples of the radical-polymerization-type negative resist include a mixture of an acrylic monomer, a photoradical polymerization initiator, and the plasticizer mentioned above, however, the plasticizer is not essential. Examples of the photo-crosslinking-type negative resist include a mixture of a polyhydroxystyrene (PHSt) polymer, a binder such as melamine, and a photoacid generator.

The dots 13 are each formed in, for example, a cylindrical shape, however, may also be formed in the shape of a triangular prism, a quadrangular prism, a polygonal prism, an elliptical prism, and so forth. The dots 13 are formed over the entire surface of the bonding surface 12, however, are not limited to this example, and may be formed on a certain region of the bonding surface 12.

A method for forming the dots 13 will be described below. To form the dots 13, commonly known lithography techniques can be used. First, a resist is applied on the base material 11. When applying the resist, a commonly known coating device and coating method can be used. For example, in a spin coating method, a certain amount of the resist is dispensed from a nozzle onto the base material 11, and the base material 11 is rapidly rotated to spread the resist on the base material 11. A commonly known coating method such as a spray method or a slit nozzle method may also be used as the resist coating method instead of a spin coating method.

Subsequently, prebaking is performed on the base material 11 by heating it at 70° C. to 130° C. to remove the solvent contained in the resist. Next, using an exposure device, exposure light is irradiated onto the resist through a mask that is preliminarily fabricated to match the outer diameter (pattern) of the dots 13. A development process is then performed to form the dots 13. The shape of each dot 13 in plan view is set by the mask mentioned above, and the height of the dot 13 is set according to the thickness of the resist film.

The semiconductor substrate 21 (laminate 20) is supported by the substrate support 10 via the dots 13. The laminate 20 includes the semiconductor substrate 21, a first adhesive layer 22, a reaction layer 23, and a first support 24. The first adhesive layer 22 is formed of a material different from the material of the adhesive layer 14. The semiconductor substrate 21 has a first surface 25 on the first support 24 side and a second surface 26 on the opposite side of the first surface 25. It should be noted that FIG. 1 shows the circuit patterns 21A individualized from the semiconductor substrate 21. The circuit patterns 21A are formed using, for example, a lithography technique or the like, as will be described later.

The first adhesive layer 22 is provided between the semiconductor substrate 21 (circuit patterns 21A) and the reaction layer 23. The first adhesive layer 22 is in contact with the semiconductor substrate 21 and supports the semiconductor substrate 21 (or the circuit patterns 21A). The first adhesive layer 22 is formed using a commonly known technique. For example, the first adhesive layer 22 is formed by applying an adhesive for forming the first adhesive layer 22 to the reaction layer 23. The method of applying the adhesive is not particularly limited, and any commonly known method can be used. Regarding the application of the adhesive, an application method such as spin coating method, roller blade method, spin coating method, slit nozzle method, or chemical vapor deposition (CVD) method is used, for example. The thickness of the first adhesive layer 22 is preferably within the range of 1 μm to 200 μm, and more preferably within the range of 5 μm to 150 μm, for example. It is also preferable that the thickness of the first adhesive layer 22 be thicker than that of the reaction layer 23.

Examples of the composition for forming the first adhesive layer 22 include various compositions commonly known in the art, such as acrylic-based, novolac-based, naphthoquinone-based, hydrocarbon-based, polyimide-based, elastomer, and polysulfone-based. Examples of the composition also include those containing other components such as thermoplastic resin, diluting solvent, and additive. The thermoplastic resin may be any material that exhibits adhesive strength, such as hydrocarbon resin, acrylic-styrene resin, maleimide resin, elastomer resin, and polysulfone resin, or a combination thereof may preferably be used. It should be noted that the composition includes a diluting solvent.

The reaction layer 23 is arranged between the first support 24 and the first adhesive layer 22. The reaction layer 23 undergoes alteration upon light exposure, heat application, or immersion in a solvent. The term “alteration” of the reaction layer 23 here refers to a phenomenon that can bring the reaction layer 23 into a state in which it can be destroyed upon receiving a slight external force, or a state in which the adhesion between the reaction layer 23 and the layer in contact therewith is reduced. For example, the reaction layer 23 is formed by applying a solution for forming the reaction layer 23 to the first support 24. The method of applying the solution is not particularly limited, and any commonly known method can be used. Regarding the application of the solution, an application method such as spin coating method, roller blade method, splay method, slit nozzle method, or chemical vapor deposition (CVD) method is used, for example. The reaction layer 23 may also be provided by chemical vapor deposition (CVD).

For example, the thickness of the reaction layer 23 is preferably 0.05 μm to 50 μm, and even more preferably 0.3 μm to 1 μm. With a thickness ranging between 0.05 μm and 50 μm, the reaction layer 23 can undergo desired alteration through brief exposures to light and low-energy light, brief heat application, or brief immersion in a solvent. For the sake of productivity, it is particularly preferable that the thickness of the reaction layer 23 be within the range of 1 μm or less.

Here, as a composition for forming the reaction layer 23, it is sufficient if the substance forming the reaction layer 23, as mentioned above, has a property to alter through brief exposures to light and low-energy light, brief heat application, or brief immersion in a solvent. As for the composition, for example, it contains a resin component with a phenolic skeleton, a polymer with repeating units containing a light-absorbing structure, a fluorocarbon, an inorganic substance, a compound having an infrared-absorbing structure, an infrared-absorbing substance, a reactive polysilsesquioxane, or a combination of these. The composition may contain optional components such as a filler, a plasticizer, a thermal acid generator component, a photoacid generator component, an organic solvent component, a surfactant, a sensitizer, and a component that can improve the separability of the support substrate.

The first support 24 is bonded to the semiconductor substrate 21 through the reaction layer 23 and the first adhesive layer 22, and it is desirable that the first support 24 have the necessary strength to prevent damage to or deformation of the semiconductor substrate 21. For the first support 24, a glass substrate is used, for example. The shape of the first support 24 in plan view is, for example, circular to match the semiconductor substrate 21, however, is not particularly limited. The first support 24, in plan view, may be of, for example, a rectangular shape, a polygonal shape, an elliptical shape, an elongated elliptical shape.

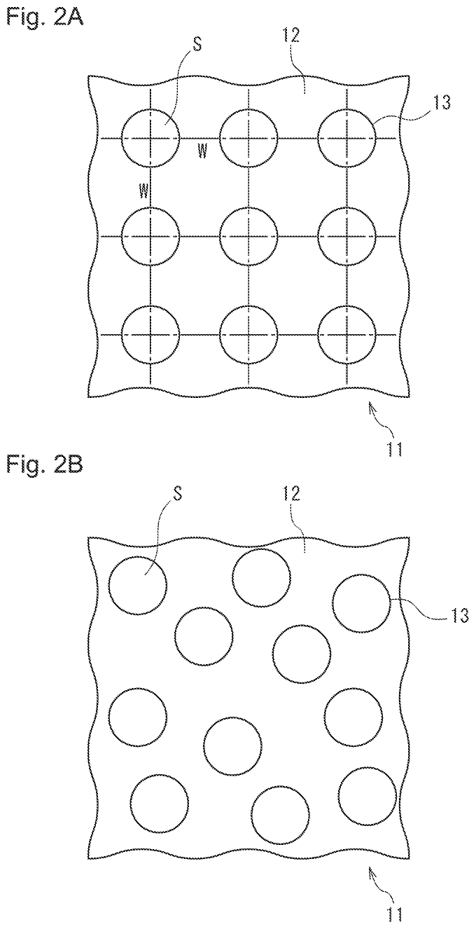

FIG. 2A and FIG. 2B are exemplified plan views of an enlarged portion of the substrate support 10, FIG. 2A showing an example a dot pattern. As shown in FIG. 2A, each dot 13 is provided having an equal area S in plan view, and the plurality of dots 13 are systematically arranged in a grid pattern. The plurality of 13 are arranged at equal intervals. In other words, the distances W between the centers of the dots 13 are equal.

### Modified Example 1

FIG. 2B is a diagram showing an example of a dot pattern according to Modified Example 1. As shown in FIG. 2B, each dot 13 is provided having an equal area S in plan view, as with the example of FIG. 2A. The plurality of dots 13 are arranged discretely (in a scattered or unsystematic manner). In other words, the distances between the centers of the dots 13 are not equal.

Thus, the dots 13 may be arranged systematically or discretely in plan view. It should be noted that the area S can be appropriately set, taking into consideration of the weight of the semiconductor substrate 21 (laminate 20), the size of the circuit pattern 21A, and so forth. Similarly, the distances between the centers of the dots 13 can be set as appropriate.

### Modified Example 2

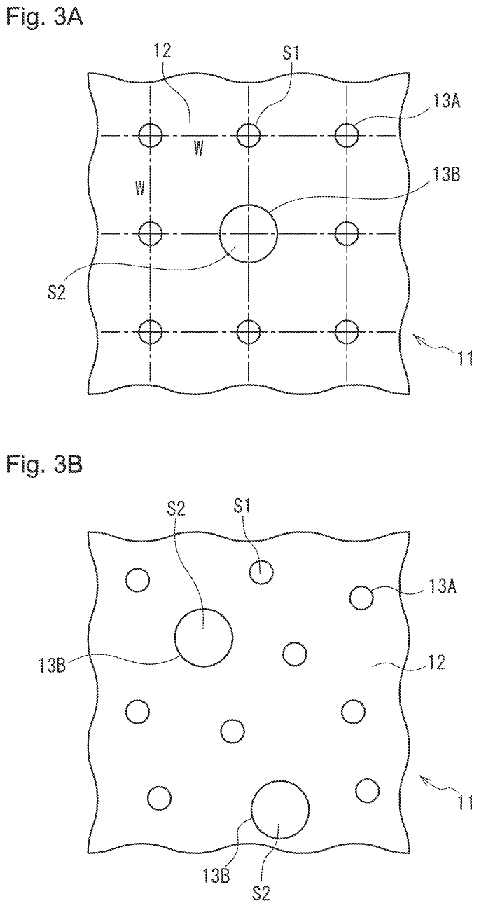

FIG. 3A and FIG. 3B are exemplified plan views of an enlarged portion of the substrate support 10, FIG. 3A showing an example a dot pattern according to Modified Example 2. As shown in FIG. 3A, a plurality of dots 13A and a dot 13B are provided with different areas S1, S2, respectively, when viewed in plan. The area S1 of the dot 13A is smaller than the area S2 of the dot 13B. The dots 13A and the dot 13B are systematically arranged in a grid pattern, and the plurality of dots 13A are arranged so as to surround one dot 13B. The distances W between the centers of the dots 13A and the distances W between the centers of the dots 13A and the dot 13B are equal.

### Modified Example 3

FIG. 3B is a diagram showing an example of a dot pattern according to Modified Example 3. As shown in FIG. 3B, a plurality of dots 13A and a plurality of dots 13B are provided with different areas S1, S2, respectively, when viewed in plan, as with the dots 13A and the dot 13B of FIG. 3A. The dots 13A and the dots 13B are both arranged discretely. The number of the dots 13A is smaller than the number of the dots 13B. Therefore, when viewed in plan, the dots 13B having a larger area S2 are not arranged close to each other, and multiple dots 13A are arranged so as to surround one dot 13B as in FIG. 3A. The distance between the centers of the dots 13A and the distance between the dots 13B are not equal.

Thus, the dots 13 may be provided in a configuration such that the dots 13A and the dots 13B have different areas S1, S2, respectively. The areas S1, S2 can be set as appropriate, taking into consideration of the weight of the semiconductor substrate 21 (laminate 20), the size of the circuit pattern 21A, and so forth. Similarly, the distance between the centers of the dots 13A and the distance between the dots 13B can also be set as appropriate. It should be noted that in Modified Examples 2 and 3, the dots 13A and the dots 13B have two different areas S1, S2, however, the invention is not limited to these examples. For example, the dots 13 having three different areas may be provided. Furthermore, the invention is not limited to surrounding each dot 13B having a larger area S2 with multiple dots 13A having a smaller area S1, and the dots 13B may also be arranged in proximity to each other.

In the embodiment and the Modified Examples described above, the dots 13 (13A, 13B) may be provided such that the total areas thereof per unit area (for example, per square centimeter) are equal on the bonding surface 12 of the base material 11, or that the total areas thereof per unit area are not equal in a certain region of the bonding surface 12.

### Modified Example 4

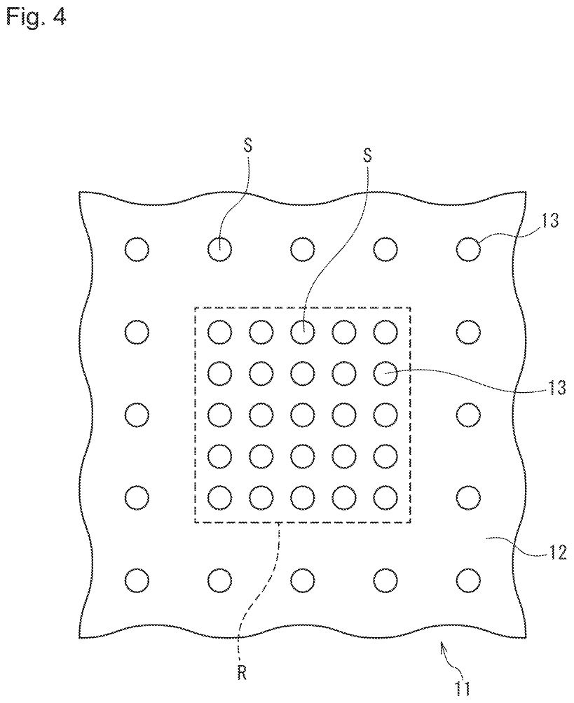

FIG. 4 is an exemplified plan view of an enlarged portion of the substrate support 10, showing a dot pattern according to Modified Example 4. As shown in FIG. 4, in a portion of the bonding surface 12, the total areas of the dots 13 per unit area (for example, per square centimeter) varies in a region R and the region other than the region R. In the region R, the total area of the dots 13 per unit area is larger than that in the region other than the region R. In other words, the density of the dots 13 is higher in the region R than in the region other than the region R. That is to say, the region R is a high-density region of the dots 13. In the region R, the distance between the centers of the dots 13 is set shorter than that in the region other than the region R.

The the region R can arbitrarily be set on the bonding surface 12. For example, the region R may be arranged discretely on the bonding surface 12, or may be arranged in a large number in the center portion or the outer periphery portion of the bonding surface 12. In Modified Example 4, the dots 13 having the same area in plan view are used in the region R and the region other than the region R, however, the invention is not limited to this example. Dots 13 having varying areas may be used in the region R and in the region other than the region R. It should be noted that the shape of the region R when viewed in plan is not limited to being rectangular, and may also be circular, elliptical, elongated elliptical, or polygonal.

### Second Embodiment

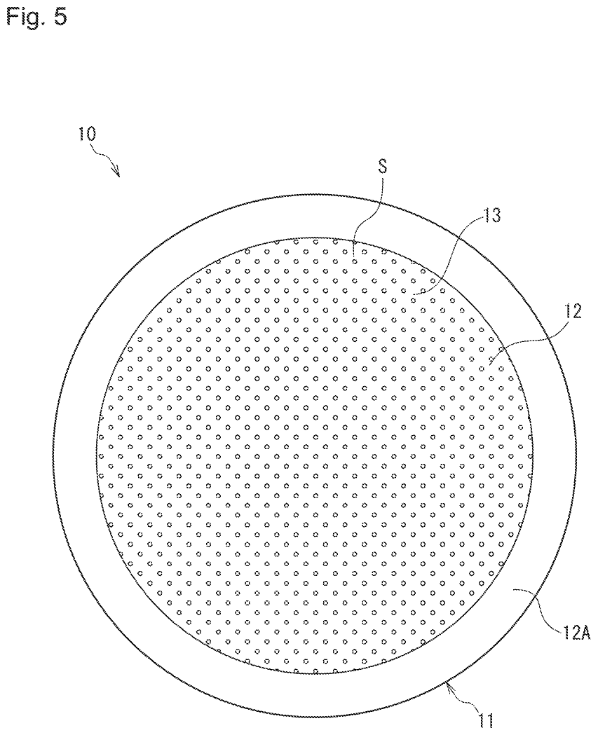

FIG. 5 is a plan view showing an example of the substrate support 10 according to Second Embodiment. As shown in FIG. 5, the substrate support 10 have dots 13 formed on the inner side of an outer peripheral portion 12A, which is on the outer peripheral edge side of the bonding surface 12. The outer peripheral portion 12A is a ring-shaped portion having a constant width from the outer edge of the base material 11, and the width of the outer peripheral portion 12A can be set arbitrarily. The outer peripheral portion 12A is a portion uniformly coated with a negative resist serving as the adhesive layer 14. The area ratio between the outer peripheral portion 12A and the portions other than the outer peripheral portion 12A can be appropriately set, taking into consideration of the weight of the semiconductor substrate 21 or the laminate 20.

The dots 13 formed inside the outer peripheral portion 12A may be arranged systematically in a grid pattern as described above, or may be arranged discretely. Furthermore, the areas S of the plurality of dots 13 may or may not be equal. According to Second Embodiment, the semiconductor substrate 21 (laminate 20) can be reliably retained on the substrate support 10 by the adhesive layer 14 of the outer peripheral portion 12A. Since the dots 13 are formed on the inner side of the outer peripheral portion 12A, the adhesion to the circuit pattern 21A is lowered as in First Embodiment. This facilitates the effortless pickup of the circuit pattern 21A. It should be noted that the adhesive layer 14 may not be provided on the outer peripheral portion 12A.

### Third Embodiment

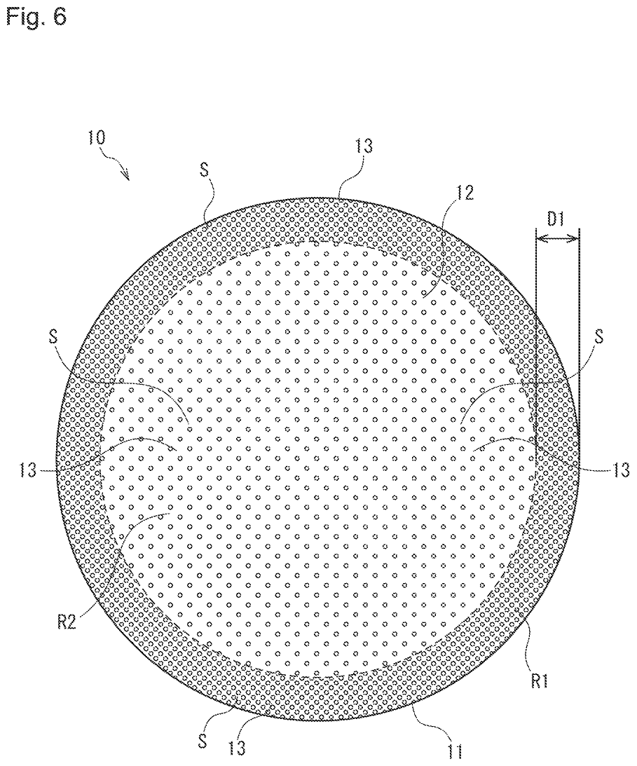

FIG. 6 is a plan view showing an example of the substrate support 10 according to Third Embodiment. As shown in FIG. 6, the substrate support 10 has a first region R1 and a second region R2 on the bonding surface 12. The first region R1 is set in a ring shape with a width D1 extending inward from the outer peripheral edge of the base material 11. The width D1 is approximately 2 mm to 25 mm, for example, and is preferably approximately 3 mm to 10 mm. The second region R2 is arranged on the inner side of the first region R1, and the outer edge thereof is of a circular shape. The occupancy ratio of the dots 13 per unit area varies between the first region R1 and the second region R2. In the first region R1, the occupancy ratio of the dots 13 is 18% to 50%, preferably 18% to 35%. In the second region R2, the occupancy ratio of the dots 13 is 0.13% to 0.79%, preferably 0.18% to 0.6%.

The occupancy ratio of the dots 13 per unit area in the first region R1 is higher than the occupancy ratio of the dots 13 per unit area in the second region R2. In other words, the density of the plurality of dots 13 is higher in the first region R1 than the density of the plurality of dots 13 in the second region R2. The first region R1 is a high-density region of dots 13, and the second region R2 is a low-density region of dots 13. In Third Embodiment, the area S of each dot 13 in plan view is the same between the first region R1 and the second region R2, however, the area of the dots 13 may vary between the first region R1 and the second region R2.

According to Third Embodiment, the adhesion to the semiconductor substrate 21 (laminate 20) varies between the first region R1 and in the second region R2. In other words, according to Third Embodiment, the adhesion to the semiconductor substrate 21 in the first region R1 may be increased to ensure reliable retention of the semiconductor substrate 21 while concurrently reducing the adhesion of the semiconductor substrate 21 in the second region R2. As a result, the circuit pattern 21A can be effortlessly picked up as in First Embodiment. It should be noted that the occupancy ratio of the dots per unit area in the first region R1 may be lower than the occupancy ratio of the dots 13 per unit area in the second region R2.

### Modified Example 5

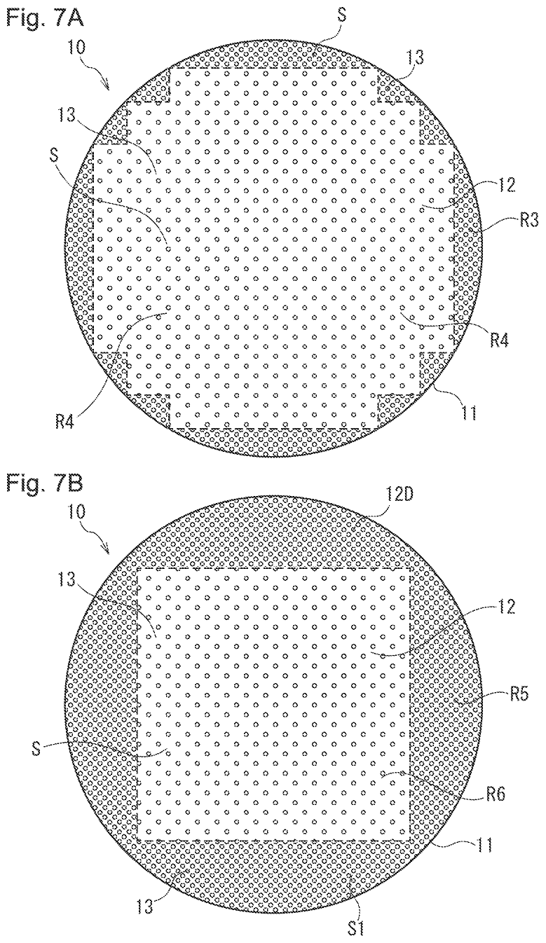

FIG. 7A is a plan view showing the substrate support 10 according to Modified Example 5. As shown in FIG. 7A, the substrate support 10 has a first region R3 and a second region R4 on the bonding surface 12. The second region R4 is arranged on the inner side of the first region R3. The inner edge of the first region R3 (the outer edge of the second region R4) is formed in a stepped shape. This stepped shape can be formed, for example, by using a stepper (reduction projection exposure device) to perform exposure on rectangular exposure areas in a step-and-repeat manner. In other words, rectangular exposure areas partially remain on the inner edge of the first region R3, resulting in a stepped shape. Hence, there is no need for the inner edge of the first region R3 to be curved, making the production of the substrate support 10 more straightforward.

In the substrate support 10 of Modified Example 5, the occupancy ratio of the dots 13 per unit area in the first region R3 may be higher or lower than that of the dots 13 per unit area in the second region R4. The occupancy ratio of the dots 13 in the first region R3 is 18% to 50%, preferably 18% to 35%, as in Third Embodiment described above. In the second region R4, the occupancy ratio of the dots 13 is 0.13% to 0.79%, preferably 0.18% to 0.6%. Furthermore, the area S of the dot 13 may or may not be equal in the first region R3 and in the second region R4.

### Modified Example 6

FIG. 7B is a plan view showing the substrate support 10 according to Modified Example 6. As shown in FIG. 7B, the substrate support 10 has a first region R5 and a second region R6 on the bonding surface 12. The second region R6 is arranged on the inner side of the first region R5. The inner edge of the first region R5 (the outer edge of the second region R6) is formed in a rectangular shape. This rectangular shape can be formed, for example, by using a stepper (reduction projection exposure device) mentioned above. Hence, there is no need for the inner edge of the first region R5 to be curved, making the production of the substrate support 10 more straightforward.

In the substrate support 10 of Modified Example 6, the occupancy ratio of the dots 13 per unit area in the first region R5 may be higher or lower than that of the dots 13 per unit area in the second region R6. The occupancy ratio of the dots 13 in the first region R5 is 18% to 50%, preferably 18% to 35%, as in Third Embodiment described above. In the second region R6, the occupancy ratio of the dots 13 is 0.13% to 0.79%, preferably 0.18% to 0.6%. Furthermore, the area S of the dot 13 may or may not be equal in the first region R5 and in the second region R6.

### Fourth Embodiment

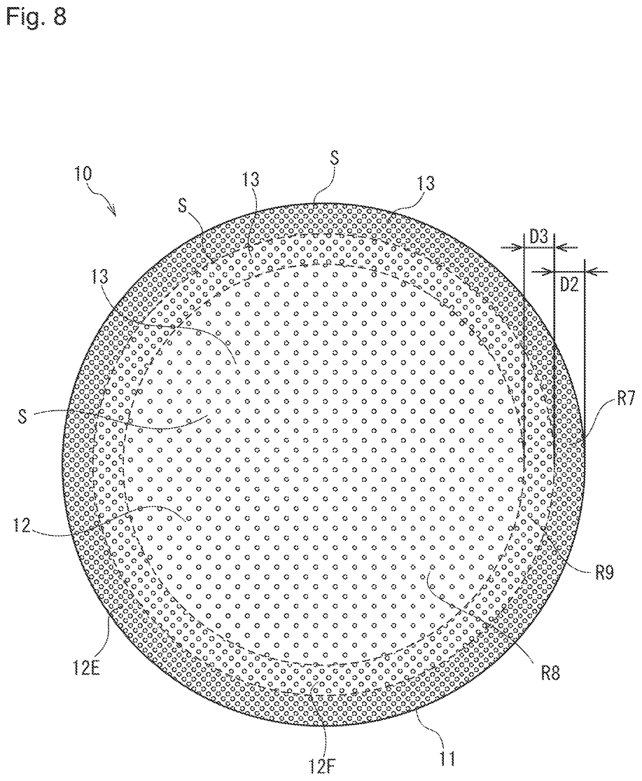

FIG. 8 is a plan view showing an example of the substrate support 10 according to Fourth Embodiment. As shown in FIG. 8, the substrate support 10 has a first region R7, a second region R8, and a third region R9 on the bonding surface 12. The first region R7 is set in a ring shape with a width D2 extending inward from the outer peripheral edge of the base material 11. The width D2 is approximately 2 mm to 25 mm, for example, and is preferably approximately 3 mm to 10 mm. The second region R8 and the third region R9 are arranged on the inner side of the first region R7. The third region R9 is arranged between the first region R7 and the second region R8. The third region R9 is set in a ring shape with a width D3 extending inward from the outer edge thereof. The width D3 is, for example, approximately 0.05 mm to 10 mm, and is preferably approximately 0.1 mm to 0.5 mm. The second region R8 is arranged on the inner side of the third region R9, and the outer edge thereof is of a circular shape.

The occupancy ratio of the dots 13 per unit area varies between the first region R7, the second region R8, and the third region R9. The occupancy ratios of dots 13 in the first region R7, the second region R8, and the third region R9 are specified as follows. In the first region R7, the occupancy ratio is 18% to 50%, preferably 18% to 35%. In the second region R8, the occupancy ratio of the dots 13 is 0.13% to 0.79%, preferably 0.18% to 0.6%. In the third region R9, the occupancy ratio of the dots 13 is 0.79% to 18%, preferably 0.79% to 2%. The occupancy ratio of the dots 13 per unit area in the first region R7 is higher than the occupancy ratio of the dots 13 per unit area in the second region R8 and the third region R9. Also, the occupancy ratio of the dots 13 per unit area in the third region R9 is higher than the occupancy ratio of the dots 13 per unit area in the second region R8. In other words, the occupancy ratio of the dots 13 decreases from the outer peripheral edge side of the bonding surface 12 in the first region R7 to the third region R9, and from the outer side to the inner side in the second region R8. That is to say, the density of the dots 13 decreases with approach from the first region R7 to the third region R9 and the second region R8.

In Fourth Embodiment, the area S of each dot 13 in plan view is the same between the first region R7, the second region R8, and the third region R9, however, the area of the dot 13 may vary between the first region R7, the second region R8, and the third region R9.

According to Fourth Embodiment, the adhesion with respect to the semiconductor substrate 21 (laminate 20) gradually decreases with approach from the outer peripheral edge of the bonding surface 12 to the center. Therefore, the adhesion increases on the outer peripheral edge side of the semiconductor substrate 21 and gradually decreases towards the center, and as a result, the semiconductor substrate 21 can be reliably retained by the substrate support 10, and this facilitates the effortless pickup of the circuit pattern 21A. Moreover, as in Fourth Embodiment, the invention is not limited to progressively reducing the occupancy ratio of the dots 13 from the first region R7 to the second region R8 and then to the third region R9. For example, the occupancy ratio of the dots 13 may be progressively increased from the first region R7 to the third region R9 and then to the second region R8, or the occupancy ratio of the dots 13 may be made the highest in the third region R9.

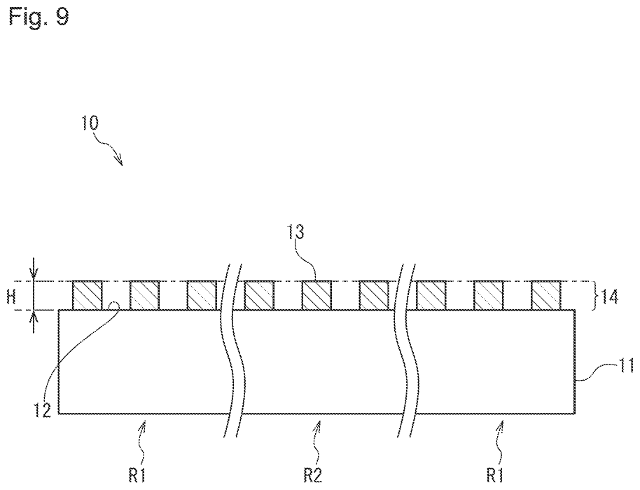

FIG. 9 is a side view showing a dot pattern example. FIG. 9 shows the dots 13 of First Embodiment as viewed from the side. As shown in FIG. 9, the dots 13 are all provided with a height H. The height H of the dots 13 is set by the thickness of the negative resist forming the adhesive layer 14, as described above. The dots 13 in Second to Fourth Embodiments (including the dots 13A, 13B of above Modified Examples 2 and 3) may also be provided with a constant height H. The height H is, for example, 4 μm to 20 μm, preferably 4 μm to 10 μm. If the height H is less than 4 μm, there is a risk of bonding failure, and if it exceeds 20 μm, there is a risk of dots toppling during the bonding process.

### Modified Example 7

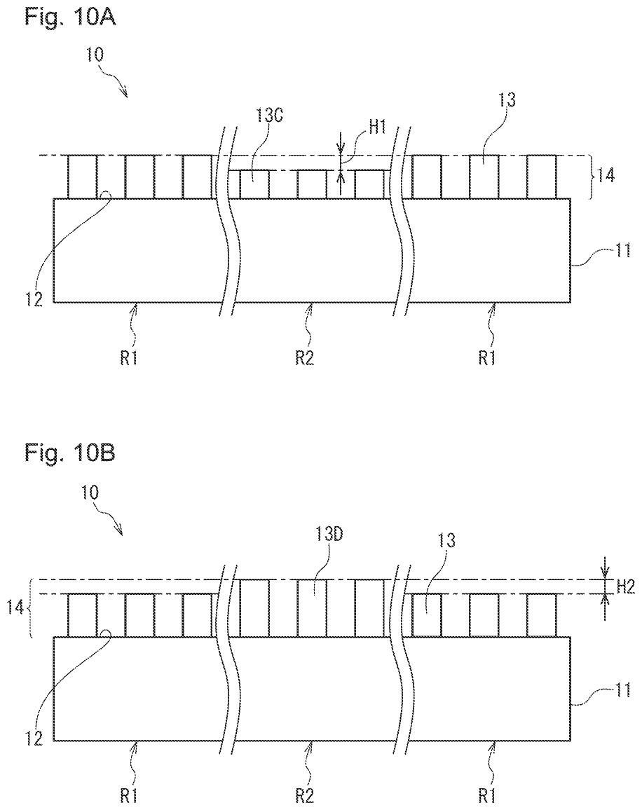

FIG. 10A is a side view showing a dot pattern according to Modified Example 7. As shown in FIG. 10A, it is acceptable to change the height of the dots 13 in certain regions of the bonding surface 12. In FIG. 10A, there is a difference in height between the dots 13 in the first regions R1, R3, R5 of Second Embodiment and Modified Examples 5 and 6, and the dots 13C in the second regions R2, R4, R6. In the example shown in FIG. 10A, the height of the dots 13 in the first region R1 is set higher than the height of the dots 13C in the second region R2 by a difference H1. The difference H1 is set to be ±5% or less of the height of the dots 13 in the first region R1 and so forth, for example.

According to Modified Example 7, the dots 13C are lower in the center portion of the bonding surface 12, and accordingly, lower adhesion can be achieved in the center portion while ensuring high adhesion in the outer peripheral portion of the semiconductor substrate 21 when bonding together the semiconductor substrate 21 (laminate 20) and the substrate support 10. Therefore, the semiconductor substrate 21 can be reliably retained by the substrate support 10, and this facilitates the effortless pickup of the circuit pattern 21A.

### Modified Example 8

FIG. 10B is a side view showing a dot pattern according to Modified Example 8. As shown in FIG. 10B, the height of dots 13D in the second regions R2, R4, R6 is set higher by a difference H2 than the height of the dots 13 in the first regions R1, R3, R5 of Second Embodiment and Modified Examples 5 and 6. The difference H2 is set to be ±5% or less of the height of the dots 13 in the first region R1 and so forth, for example.

According to Modified Example 8, the dots 13D are higher in the center portion of the bonding surface 12, and accordingly, lower adhesion can be achieved in the outer peripheral portion while ensuring higher adhesion in the center portion of the semiconductor substrate 21 when bonding together the semiconductor substrate 21 (laminate 20) and the substrate support 10. Moreover, the height of the dots 13 may be set differently between the first region R7, the second region R8, and the third region R9 of Fourth Embodiment described above. For example, the height of the dots 13 may be progressively reduced from the first region R7 to the third region R9 and then to the second region R8.

As with Modified Examples 7 and 8, the height difference of the dots 13C, 13D in the second regions R2, R4, R6 is preferably within +5% with respect to the dots 13 in the first regions R1, R3, R5, which are on the outer peripheral edge side of the bonding surface 12.

### Circuit Pattern (Semiconductor Device) Production Method:

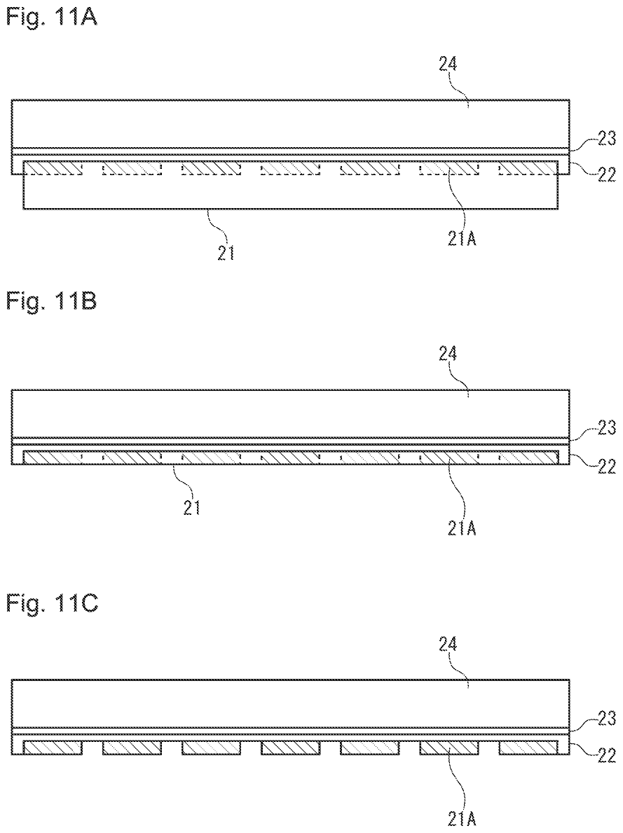

FIG. 11A to FIG. 13 show an example of a method for producing circuit patterns 21A (semiconductor devices). First, a laminate 20 is produced as shown in FIG. 11A. A plurality of circuit patterns 21A are formed in the semiconductor substrate 21, using a commonly known technique such as lithography. Meanwhile, using, for example, a spin coating method, a composition for forming the reaction layer 23 is applied onto the first support 24, and heat application is performed on it at 200° C. to 350° C. for a certain duration to thereby form the reaction layer 23. Subsequently, using, for example, a spin coating method, a composition for forming the first adhesive layer 22 is applied onto the reaction layer 23, and heat is applied at 200° C. for a certain duration, to thereby form the first adhesive layer 22. The first adhesive layer 22 may be formed (film-formed) on the circuit patterns 21A. Subsequently, the first adhesive layer 22 is brought into contact with the surface, on which the circuit patterns 21A are formed, and the first support 24 and the semiconductor substrate 21 are press-bonded together, to thereby form the laminate 20. In the process of press-bonding the first support 24 and the semiconductor substrate 21, a pressure of 1,000 kgf to 4,000 kgf is applied while applying heat at a temperature between 180° C. and 220° C.

Next, as shown in FIG. 11B, the semiconductor substrate 21 being the laminate 20 is subjected to a thinning process. Using a commonly known polishing device, the surface of the semiconductor substrate 21 opposite side of the circuit patterns 21A is polished. The semiconductor substrate 21 is polished, for example, to the extent that polishing reaches the proximity of the circuit patterns 21A. Next, as shown in FIG. 11C, the semiconductor substrate 21 is subjected to a dicing process. The dicing process is performed using a dicing saw along scribe lines (dicing lines) set between the circuit patterns 21A, for example. During the dicing process, for example, the dicing saw reaches the first adhesive layer 22 to reliably cut and separate the circuit patterns 21A.

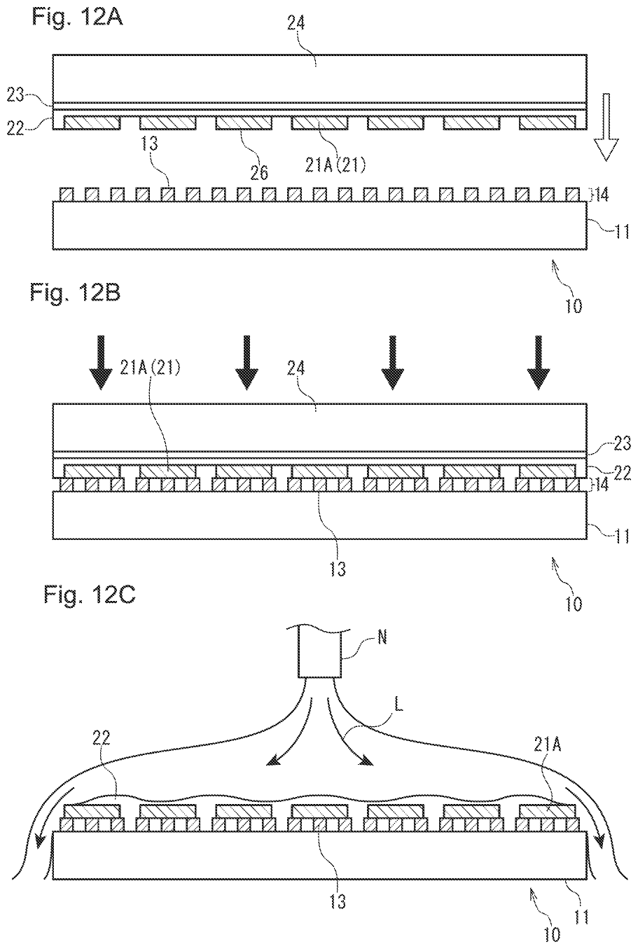

Next, as shown in FIG. 12A, the substrate support 10 is bonded to the semiconductor substrate 21 (circuit patterns 21A). For example, a substrate bonding device is used to bond the semiconductor substrate 21 and the substrate support 10 together. For example, the substrate support 10 is placed on a table not shown in the drawings with the dots 13 facing upwards, and then the laminate 20 is brought in above the substrate support 10, with the circuit patterns 21A facing downwards. Subsequently, the semiconductor substrate 21 is pressed downward with a plate not shown in the drawings from above the laminate 20, to thereby bond together the semiconductor substrate 21 and the substrate support 10. At this time, these two are heated at a temperature of approximately 50° C. to 150° C. and bonded together with a pressing force of approximately 100 kgf to 4,000 kgf.

Next, as shown in FIG. 12B, an irradiation device not shown in the drawings irradiates light onto the reaction layer 23 from the side where the reaction layer 23 is absent on the first support 24, thereby causing the reaction layer 23 toalter. The light is transmitted through the first support 24 to be irradiated onto the reaction layer 23. As the light, light with a wavelength capable of causing the reaction layer 23 to alter is used. Examples of this light include UV laser and light emitted from a high-pressure mercury lamp. Subsequently, a suction device or the like lifts the first support 24, causing a destruction of the reaction layer 23 that has altered, and the first support 24 is debonded from the circuit patterns 21A (semiconductor substrate 21).

Next, the circuit patterns 21A are cleaned as shown in FIG. 12C. After the debonding of the first support 24, the first adhesive layer 22 remains on the surface of the circuit patterns 21A. Therefore, to remove the first adhesive layer 22, cleaning is performed using a cleaning fluid L. For cleaning, a commonly known cleaning device can be used. The cleaning fluid L is discharged from a cleaning fluid supply nozzle N to remove the first adhesive layer 22 remaining on the surface of the circuit patterns 21A. The cleaning fluid L used dissolves the first adhesive layer 22 but does not dissolve the negative resist, which constitutes the composition of the dots 13. As the cleaning fluid L, a hydrocarbon solvent, an ester solvent, or a mixture thereof may be used, and examples include p-menthane, decalin, propylene glycol monomethyl ether acetate (PGMEA).

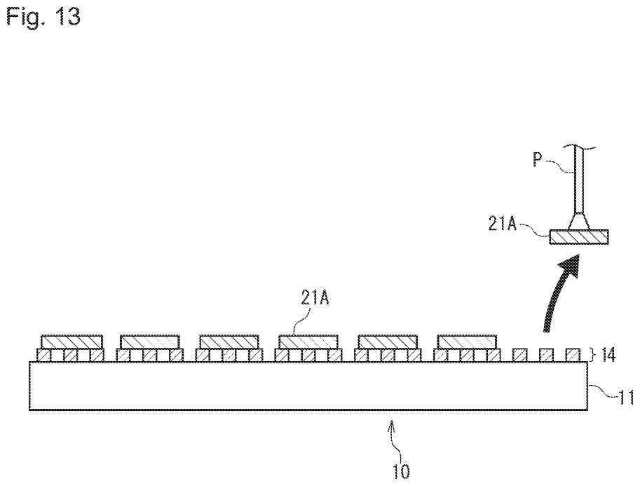

Next, the circuit patterns 21A are picked up from the substrate support 10, as shown in FIG. 13. After removing the first adhesive layer 22 and allowing it to dry, a single circuit pattern 21A is picked up using a suction pad P of a pickup device. Then, the suction pad P is lifted to debond the circuit pattern 21A from the substrate support 10 (dots 13). By repeating this operation, the circuit patterns 21A are extracted from the substrate support 10.

### Examples

The following describes examples of the substrate support 10. Exposure and development were performed on a 300 mm diameter silicon wafer (semiconductor substrate 21) through the use of a mask to fabricate multiple circuit patterns 21A. Meanwhile, following the fabrication of the reaction layer 23 on a 300 mm diameter glass substrate (first support 24), the first adhesive layer 22 was fabricated on the reaction layer 23. Subsequently, a laminate 20 was fabricated by applying pressure of 4,000 Kgf and heat at 215° C. for 4 minutes, press-bonding together the silicon wafer and the glass substrate. Next, the silicon wafer was subjected to thinning and dicing to form individual circuit patterns 21A in the laminate 20.

A plurality of substrate supports 10 with different patterns of dots 13 were prepared, the laminate 20 formed as described above was bonded to each substrate support 10, and the glass substrate was debonded from the laminate 20. Subsequently, the circuit patterns 21A were debonded from the substrate supports 10 to evaluate the chip fly-off and debondability of the circuit patterns 21A. The circuit patterns 21A were debonded from the substrate support 10 by attaching an adhesive pad with a diameter of 15 mm and lifting it. The evaluation of chip fly-off was performed visually, while debondability was evaluated by the maximum load force required during the lifting of the adhesive pad. “Chip fly-off” here refers to a phenomenon where the chips (circuit patterns 21A) are unintentionally dislodged from the substrate support 10 during the process of cleaning the first adhesive layer 22 with the cleaning fluid L after the glass substrate has been debonded from the laminate 20. Examples of chip fly-off patterns include, as mentioned above, a state in which the chip is dislodged from the substrate support 10, a state in which the dislodged chip flies off and falls onto another location, and a state in which a portion of the chip is dislodged, creating a slope thereon.

In Example 1, a substrate support 10 was fabricated for a 12-inch silicon wafer (base material 11), following SEMI standard specifications, with a thickness of 775 μm and a diameter of 300 mm, by arranging cylindrical dots 13 in a systematic manner on the bonding surface 12 of the silicon wafer. It should be noted that the dot occupancy ratio was determined using the following formula.

Dot occupancy ratio (%)=(dot area on base material/area of base material)×100

In Example 1, while it was possible to debond the circuit patterns 21A with a force of less than 10 N, there was a slight occurrence of fly-off (less than 1%).

In Comparative Example 3, an adhesive layer 14 (referred to as flat-film) with a thickness of 10 μm was formed on the entire surface of the silicon wafer, as with Example 1. This substrate support was considered as having one dot 13 formed thereon. The other aspects remained consistent with Example 1. Therefore, in Comparative Example 3, the dot diameter was the same as the diameter of the silicon wafer, the distance between dot centers was 0 μm, and the dot occupancy ratio was 100%.

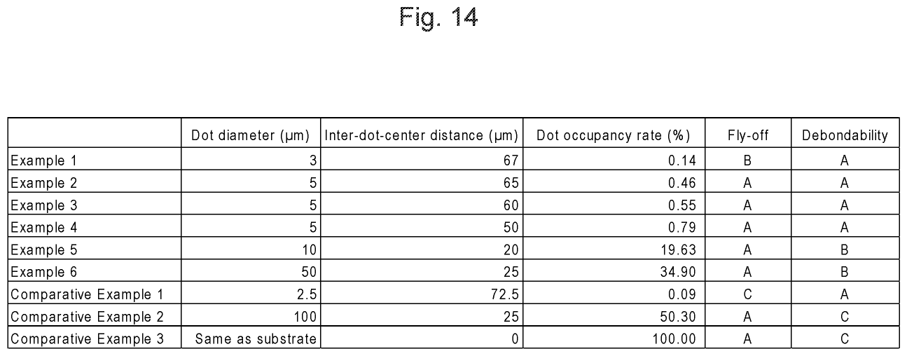

The silicon wafers used in the Examples and the Comparative Examples other than Example 1 and Comparative Example 3 were the same as those in Example 1. FIG. 14 is a diagram showing test results of the substrate supports 10 in Examples 1 to 6 and Comparative Examples 1 to 3. In FIG. 14, “C” indicates that fly-off occurred at a ratio of 1% or higher in the chip fly-off evaluation, “B” indicates that chip fly-off occurred at a ratio of lower than 1%, and “A” indicates that no chip fly-off occurred. On the other hand, in the adhesion evaluation, “C” indicates impossible debonding with a maximum load of 20 N or greater, “B” indicates possible debonding with a load of 10 N or greater but less than 20 N, and “A” indicates possible debonding with a load of less than 10 N.

As shown in FIG. 14, in Examples 1 to 6, for the substrate support 10 with a dot occupancy ratio between 0.14% and 34.90%, it was confirmed that fly-off of the circuit pattern 21A was minimal, and in the rare instances it occurred, it was negligible. Also, regarding debondability, it was confirmed that debonding of the circuit pattern 21A from the substrate support 10 was possible with a minimal force, specifically less than 20 N. Accordingly, it was confirmed in Examples 1 to 6 that during the pickup of the circuit pattern 21A, there was no chip fly-off, and the efficient extraction of the circuit pattern 21A was possible.

On the other hand, as shown in the results of Comparative Examples 1 to 3, it was confirmed that when the dot occupancy ratio was 0.09%, 50.30%, and 100%, fly-off of the circuit pattern 21A occurred by 1% or higher (Comparative Example 1), and regarding debondability, it was also confirmed that debonding of the circuit pattern 21A was only possible with a strong force of 20 N or greater (Comparative Examples 2 and 3).

In Examples 1 to 6, the substrate support 10 of First Embodiment described above was applied. However, similar results can be obtained with, instead of this configuration, the substrate support 10 according to Second to Fourth Embodiments described above, and the substrate support 10 according to Modified Examples 1 to 8. For example, in the embodiments and the Modified Examples described above, obtaining results similar to those of Examples 1 to 6 is possible by making the dots 13 in the first regions R1, R3, R5, R7, the second regions R2, R4, R6, R8, and the third region R9 similar to those in Examples 1 to 6.

Thus, the substrate support 10 according to the embodiments, the Modified Examples, and the Examples described above includes multiple dots 13 serving as the adhesive layer 14 on the bonding surface 12 of the base material 11, and due to this low adhesion with respect to the circuit patterns 21A, the circuit patterns 21A can be effortlessly debonded from the substrate support 10. Therefore, the pickup of the circuit patterns 21A can be expedited, enabling the efficient production of the semiconductor devices. Furthermore, because the adhesion between the substrate support 10 and the semiconductor substrate 21 is low, it is possible to suppress damage to the circuit patterns 21A when debonding them from the substrate support 10.

The embodiments, the modified examples, and the examples of the present invention have been described above. However, the technical scope of the invention is not limited to the description of the embodiments, the modified examples, and the examples above. It is apparent to those skilled in the art that various modifications or improvements can be added to the embodiments, the modified examples, and the examples above. The technical scope of the present invention also encompasses one or more of such modifications or improvements. One or more of the requirements described in the embodiments, the modified examples, and the examples above may be omitted in some cases. One or more of the requirements described in the embodiments, the modified examples, and the examples above may be combined where appropriate. The order of executing processes shown in the embodiments, the modified examples, and the examples can be implemented in an arbitrary order unless the result of the previous processing is used in the following processing. While operations in the embodiments, the modified examples, and the examples above have been described with expressions such as “first”, “next”, and “subsequently” for the sake of convenience, the operations need not always be implemented in that order.

### DESCRIPTION OF REFERENCE SIGNS

10: Substrate support
11: Base material
12: Bonding surface
13: Dot
14: Adhesive layer
20: Laminate
21: Semiconductor substrate
21A: Circuit pattern (semiconductor device)
22: First adhesive layer
23: Reaction layer
25: First surface
26: Second surface
R1, R3, R5, R7: First region
R2, R4, R6, R8: Second region
R9: Third region

What is claimed is:

1. A substrate support comprising:
a base material having a bonding surface to which a semiconductor substrate is bonded; and
an adhesive layer having a pattern of dots formed in at least a portion of the bonding surface.

2. The substrate support according to claim 1, wherein each of the dots in the pattern of dots has a same area in plan view.

3. The substrate support according to claim 1, wherein the adhesive layer includes a plurality of portions with a varying dot occupancy ratio per unit area.

4. The substrate support according to claim 3, wherein the dot occupancy ratio is between 0.13% and 40%.

5. The substrate support according to claim 3, wherein the bonding surface has a first region on an outer peripheral edge thereof and a second region on an inner side of the first region.

6. The substrate support according to claim 5, wherein the first region and the second region have different dot occupancy ratios per unit area.

7. The substrate support according to claim 5, wherein the second region has an outer edge formed in a circular or polygonal shape in plan view.

8. The substrate support according to claim 5, wherein a height of dots from the bonding surface in the first region differs from a height of dots from the bonding surface in the second region.

9. The substrate support according to claim 8, wherein the height of the dots in the second region is higher than the height of the dots in the first region.

10. The substrate support according to claim 5, wherein the difference between the height of the dots from the bonding surface in the first region and the height of the dots from the bonding surface in the second region is within +5%.

11. The substrate support according to claim 5, wherein a dot occupancy ratio per unit area in the first region is higher than a dot occupancy ratio per unit area in the second region.

12. The substrate support according to claim 11,
wherein a third region is formed between the first region and the second region, and
wherein a higher dot occupancy ratio per unit area in the third region is lower than the the dot occupancy ratio per unit area in the first region and is higher than the dot occupancy ratio per unit area in the second region.

13. The substrate support according to claim 12, wherein a width of the third region is narrower than a width of the first region.

14. The substrate support according to claim 1, wherein the adhesive layer uses a material with adhesive properties that allows partial or complete debonding of the semiconductor substrate from the base material.

15. The substrate support according to claim 14, wherein the adhesive layer is formed of a negative resist.

16. The substrate support according to claim 15, wherein the negative resist is a cationic-polymerization-type negative resist, a radical-polymerization-type negative resist, or a photo-crosslinking-type negative resist.

17. The substrate support according to claim 1, wherein the base material is a silicon wafer.

18. The substrate support according to claim 1,
wherein the semiconductor substrate is a laminate with another support bonded to a first surface, and
wherein the bonding surface is bonded to a second surface of the laminate that is opposite to the first surface, to which the another support is bonded.

19. The substrate support according to claim 18, wherein the adhesive layer has lower adhesion to the semiconductor substrate compared to another adhesive layer that bonds the semiconductor substrate and the another support in the laminate.
